(19) United States
(12) Patent Application Publication
(10) Pub. No.: US 2018/0083190 A1
(43) Pub. Date: Mar. 22, 2018

(54) METHOD OF FORMING MULTIPLE NANOPATTERNS AND METHOD OF MANUFACTURING ORGANIC SOLAR CELL USING THE SAME

(71) Applicant: POSTECH ACADEMY-INDUSTRY FOUNDATION, Pohang-si (KR)

(72) Inventors: Joon Hak OH, Pohang-si (KR); Yoonho LEE, Ansan-si (KR)

(21) Appl. No.: 15/700,530

(22) Filed: Sep. 11, 2017

(30) Foreign Application Priority Data
Sep. 19, 2016 (KR) 10-2016-0119387

(51) Int. Cl. H01L 51/00; H01L 51/42

(52) U.S. Cl. CPC H01L 51/0003; H01L 51/422; H01L 51/424; H01L 51/4233; H01L 51/4226

(57) ABSTRACT

Disclosed is a method of forming multiple nanopatterns, including (a) forming a block copolymer layer on a substrate, (b) self-assembling the block copolymer layer, thus preparing a phase-separated block copolymer layer including a plurality of patterns, (c) performing stamping on the phase-separated block copolymer layer using a nanoimprinting stamp having a nano-sized pattern, (d) removing at least one from the plurality of patterns, thus preparing a multiple-nanopatterned block copolymer layer, (e) performing etching using the multiple-nanopatterned block copolymer layer as a mask, thus preparing a multiple-nanopatterned substrate, (f) subjecting the multiple-nanopatterned substrate to surface treatment, and (g) applying a liquid polymer on the multiple-nanopatterned substrate and then performing thermal treatment, thus

### BACKGROUND OF THE INVENTION

### 1. Technical Field

The present invention relates to a method of forming multiple nanopatterns and a method of manufacturing an organic solar cell using the same, and more particularly to a method of forming multiple nanopatterns, in which block copolymer lithography and nanoimprinting lithography are simultaneously applied, and to a method of manufacturing an organic solar cell using the same.

### 2. Description of the Related Art

An optoelectronic device is a device for converting electrical energy into light energy or light energy into electrical energy. The former case is exemplified by an LED (Light-Emitting Diode), and the latter case is exemplified by a solar cell.

In such an optoelectronic device, increasing the efficiency of the conversion of electrical energy into light energy or of light energy into electrical energy is regarded as important. Specifically, the LED for converting electrical energy into light energy has to possess high efficiency of extraction of light generated from electrical energy to the outside, and the solar cell for converting light energy into electrical energy has to have high efficiency of transmission or absorption of light energy incident on the surface of the cell.

To this end, in order to increase the light extraction efficiency, light absorption efficiency, and the like, on the surface of the optoelectronic device, diffuse reflection using a nanopattern may be employed, or a photonic crystal structure in which light in a desired wavelength range is filtered and amplified may be utilized.

As for the solar cell, thorough research is ongoing into increasing the light absorption efficiency by forming the nanopattern structure on the surface thereof, and the nanopattern structure is mainly formed through a photolithography process or an e-beam lithography process.

However, in the case where the photolithography process or the e-beam lithography process is applied to a large-area substrate, each lithography process has to be performed several times in order to form a pattern on a single substrate, and also, the process is relatively complicated due to the large number of processing steps, thus considerably increasing processing costs, which is undesirable.

### SUMMARY OF THE INVENTION

Accordingly, the present invention has been made keeping in mind the problems encountered in the related art, and the present invention is intended to provide a method of forming multiple nanopatterns, in which block copolymer lithography and nanoimprinting lithography are simultaneously applied, whereby multiple nanopatterns that are complicated and various may be formed at low cost.

In addition, the present invention is intended to provide a method of manufacturing an organic solar cell, in which an organic solar cell having increased light absorption efficiency may be obtained using the above method of forming multiple nanopatterns.

An aspect of the present invention provides a method of forming multiple nanopatterns, comprising: (a) forming a block copolymer layer on a substrate; (b) self-assembling the block copolymer layer, thus preparing a phase-separated block copolymer layer including a plurality of patterns; (c) performing stamping on the phase-separated block copolymer layer using a nanoimprinting stamp having a nano-sized pattern; (d) removing at least one from the plurality of patterns, thus preparing a multiple-nanopatterned block copolymer layer; (e) performing etching using the multiple-nanopatterned block copolymer layer as a mask, thus preparing a multiple-nanopatterned substrate; (f) subjecting the multiple-nanopatterned substrate to surface treatment; and (g) applying a liquid polymer on the multiple-nanopatterned substrate and then performing thermal treatment, thus preparing a multiple-nanopatterned stamp.

The plurality of patterns may include a first pattern and a second pattern.

The block copolymer layer may include at least one selected from among polystyrene-block-polymethylmethacrylate, polystyrene-block-polyvinylpyridine (polystyrene-block-poly-4-vinylpyridine, polystyrene-block-poly-2-vinylpyridine), polystyrene-block-polydimethylsiloxane, 4-(tert-butyldimethylsilyl)oxystyrene, polystyrene-block-poly(butadiene), polystyrene-block-polyimide, polystyrene-block-poly(ethylene oxide), polystyrene-block-polyferrocenylsilane, and polystyrene-block-polyferrocenylsilane-block-poly-2-vinylpyridine.

The nanoimprinting stamp may include at least one selected from among polydimethylsiloxane (PDMS), perfluorinated polyether (PFPE), polyurethane acrylate (PUA), polymethylmethacrylate (PMMA), polyvinyl alcohol (PVA), polyvinyl chloride (PVC), polycarbonate (PC), polytetrafluoroethylene (PTFE), and benzyl methacrylate.

Step (a) may include (a′) forming a block copolymer layer by applying a block copolymer solution on the substrate.

The solvent for the block copolymer solution may include at least one selected from among toluene, dichloroethylene, trichloroethylene, chloroform, chlorobenzene, dichlorobenzene, styrene, dimethylformamide, dimethylsulfoxide, xylene, cyclohexene, isopropyl alcohol, ethanol, methanol, tetrahydrofuran, terpineol, ethylene glycol, diethylene glycol, polyethylene glycol, acetonitrile, and acetone.

Step (d) may include (d′) removing at least one from the plurality of patterns by performing both wet etching and UV irradiation.

The etching in step (e) may be performed using inductive coupling plasma (ICP) etching or reactive ion etching (RIE).

The inductive coupling plasma (ICP) etching or reactive ion etching (RIE) may be independently performed by inducing CF₄/CHF₃/O₂/Ar gas to flow at a flow rate of 0.1 to 10/10 to 50/0.1 to 10/0.1 to 10 sccm.

The surface treatment in step (f) may be performed by treating the surface of the multiple-nanopatterned substrate with fluorine.

The polymer in step (g) may include at least one selected from among polydimethylsiloxane (PDMS), perfluorinated polyether (PFPE), polyurethane acrylate (PUA), polymethylmethacrylate (PMMA), polyvinyl alcohol (PVA), polyvinyl chloride (PVC), polycarbonate (PC), polytetrafluoroethylene (PTFE), and benzyl methacrylate.

Another aspect of the present invention provides an organic solar cell, comprising: a first electrode; an electron transport layer formed on the first electrode; a photoactive layer formed on the electron transport layer; a hole transport layer formed on the photoactive layer; and a second electrode formed on the hole transport layer, wherein the photoactive layer includes multiple nanopatterns.

The electron transport layer may include at least one selected from among ZnO, LiF, TiO, TiO, CsCO, and Ca.

The photoactive layer may include any one selected from the group consisting of PBDTTT-C-T, PBDTTT-CF, P3HT, PCDTBT, PCTDTBT, MEH-PPV, PTB7, PTB7-Th, PT8 and PFN and any one selected from the group consisting of PCBM and ICBA.

The hole transport layer may include at least one selected from among molybdenum oxide (MoO, MoO₃), PEDOT:PSS (poly(3,4-ethylenedioxythiophene) polystyrene sulfonate), tungsten oxide (WO₃), nickel oxide, and cerium-doped tungsten oxide (CeWO₃).

The first electrode may include at least one selected from among indium tin oxide (ITO), fluorine tin oxide (FTC)), a silver nanowire, and a silver nanomesh.

The second electrode may include at least one selected from among Au, Fe, Ag, Cu, Cr, W, Al, Mo, Zn, Ni, Pt, Pd, Co, In, Mn, Si, Ta, Ti, Sn, Pb, V, Ru, Ir, Zr, Rh, and Mg.

Still another aspect of the present invention provides a method of manufacturing an organic solar cell, comprising: (a-1) forming a first electrode; (b-1) forming an electron transport layer on the first electrode; (c-1) forming a photoactive layer on the electron transport layer and transferring multiple nanopatterns using the above multiple-nanopatterned stamp; (d-1) forming a hole transport layer on the photoactive layer; and (e-1) forming a second electrode on the hole transport layer.

According to the present invention, a method of forming multiple nanopatterns is performed in a manner in which block copolymer lithography and nanoimprinting lithography are simultaneously applied, whereby the multiple nanopatterns, which are complicated and various, can be formed at low cost. Also according to the present invention, a method of manufacturing an organic solar cell is performed in a manner in which an optoelectronic device having increased light absorption efficiency can be obtained using the method of forming the multiple nanopatterns.

### BRIEF DESCRIPTION OF DRAWINGS

FIG. 1 schematically shows a process of forming multiple nanopatterns according to the present invention;

FIGS. 2A to 2D show the principle whereby light absorption efficiency is increased by comparing the multiple nanopatterns of the present invention with a conventional single pattern;

FIGS. 3A and 3B schematically show an organic solar cell manufactured in Example 2 and a light transistor manufactured in Example 3, respectively;

FIGS. 4A to 4D show the electron microscope images of the patterns formed during the manufacturing process of Example 1;

FIGS. 5A to 5C show the results of measurement of properties of the organic solar cells manufactured in Example 2 and Comparative Examples 1 to 3; and

FIGS. 6A to 6C show the results of measurement of properties of the light transistors manufactured in Example 3 and Comparative Examples 4 to 6.

### DESCRIPTION OF SPECIFIC EMBODIMENTS

Hereinafter, embodiments of the present invention are described in detail with reference to the appended drawings so as to be easily performed by a person having ordinary skill in the art.

However, the following description does not limit the present invention to specific embodiments, and moreover, descriptions of known techniques, even if they are pertinent to the present invention, are considered unnecessary and may be omitted insofar as they would make the characteristics of the invention unclear.

The terms herein are used to explain specific embodiments and are not intended to limit the present invention. Unless otherwise stated, the singular expression includes a plural expression. In this application, the terms “include” or “have” are used to designate the presence of features, numbers, steps, operations, elements, parts, or combinations thereof described in the specification, and should be understood as not excluding the presence or additional possibility of one or more different features, numbers, steps, operations, elements, parts, or combinations thereof.

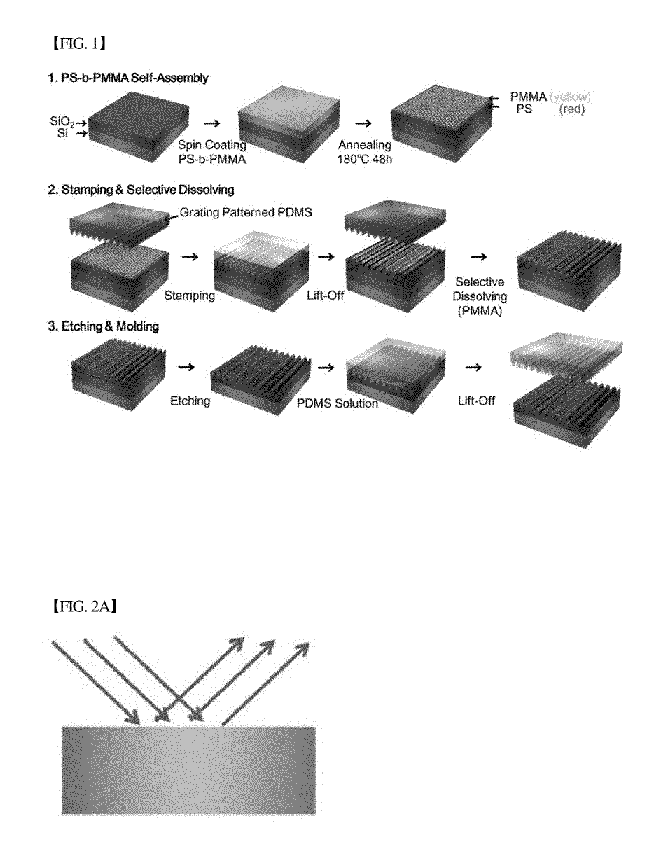

FIG. 1 schematically shows a process of forming multiple nanopatterns according to the present invention. Here, the substrate, the block copolymer layer, and the nanoimprinting stamp may be, but are not limited to, a silicon wafer (SiO₂/Si), polystyrene-block-polymethylmethacrylate (PS-b-PMMA), and polydimethylsiloxane (PDMS), respectively, which are merely set forth to illustrate but are not to be construed as limiting the present invention, and the present invention will be defined by the scope of the accompanying claims.

Below is a description of the method of forming the multiple nanopatterns according to the present invention with reference to FIG. 1.

Specifically, a block copolymer layer is formed on a substrate (step a).

The block copolymer layer may include polystyrene-block-polymethylmethacrylate, polystyrene-block-polyvinylpyridine (polystyrene-block-poly-4-vinylpyridine, polystyrene-block-poly-2-vinylpyridine), polystyrene-block-polydimethylsiloxane, 4-(tert-butyldimethylsilyl)oxystyrene, polystyrene-block-poly(butadiene), polystyrene-block-polyimide, polystyrene-block-poly(ethylene oxide), polystyrene-block-polyferrocenylsilane, and polystyrene-block-polyferrocenylsilane-block-poly-2-vinylpyridine. Preferably used is polystyrene-block-polymethylmethacrylate.

The substrate may include a silicon wafer, quartz glass, glass, etc., and is preferably a silicon wafer.

More specifically, the substrate is coated with a block copolymer solution, thus forming the block copolymer layer (step a′).

The solvent used to form the block copolymer solution may include toluene, dichloroethylene, trichloroethylene, chloroform, chlorobenzene, dichlorobenzene, styrene, dimethylformamide, dimethylsulfoxide, xylene, cyclohexene, isopropyl alcohol, ethanol, methanol, tetrahydrofuran, terpineol, ethylene glycol, diethylene glycol, polyethylene glycol, acetonitrile, and acetone. Preferably used is toluene.

Next, the block copolymer layer is self-assembled, thus preparing a phase-separated block copolymer layer including a plurality of patterns (step b).

A self-assembling process may be defined as a process of forming a disordered structure of existing components into an organized structure or pattern as a result of specific local interactions between the components themselves, without external direction.

The plurality of patterns preferably includes a first pattern and a second pattern.

Next, stamping is performed on the phase-separated block copolymer layer using a nanoimprinting stamp having a nano-sized pattern (step c).

The nanoimprinting stamp may include polydimethylsiloxane (PDMS), perfluorinated polyether (PFPE), polyurethane acrylate (PUA), polymethylmethacrylate (PMMA), polyvinyl alcohol (PVA), polyvinyl chloride (PVC), polycarbonate (PC), polytetrafluoroethylene (PTFE), and benzyl methacrylate. Preferably used is polydimethylsiloxane.

The nano-sized pattern of the nanoimprinting stamp may be transferred onto the phase-separated block copolymer layer through a stamping process.

Next, at least one of the plurality of patterns is removed, thus forming a multiple-nanopatterned block copolymer layer (step d).

When at least one of the plurality of patterns is removed, multiple nanopatterns may be formed by the nano-sized pattern transferred using the nanoimprinting stamp and by the at least one pattern that is removed.

More specifically, both wet etching and UV irradiation may be performed together, whereby at least one of the plurality of patterns may be removed (step d′).

Next, etching is performed using the multiple-nanopatterned block copolymer layer as a mask, thus preparing a multiple-nanopatterned substrate (step e).

The etching may be carried out through inductive coupling plasma (ICP) etching or reactive ion etching (RIE), with reactive ion etching (RIE) being preferably used.

Reactive ion etching (RIE) is able to induce plasma having lower energy than that of inductive coupling plasma (ICP) etching, whereby the pattern may be more precisely transferred.

The inductive coupling plasma (ICP) etching or reactive ion etching (RIE) may be independently performed by inducing CF₄/CHF₃/O₂/Ar gas to flow at a flow rate of 0.1 to 10/10 to 50/0.1 to 10/0.1 to 10 sccm.

The multiple-nanopatterned substrate may be applied to a light transistor, etc.

Next, the multiple-nanopatterned substrate is subjected to surface treatment (step f).

The surface treatment may be performed by treating the surface of the multiple-nanopatterned substrate with fluorine. Such fluorine treatment is able to decrease the binding energy of the multiple-nanopatterned substrate and the multiple-nanopatterned stamp during the preparation of the multiple-nanopatterned stamp by coating the multiple-nanopatterned substrate with a liquid polymer and then performing thermal treatment, whereby the substrate and the stamp may be easily separated from each other.

Finally, the multiple-nanopatterned substrate is coated with the liquid polymer and then thermally treated, thus preparing the multiple-nanopatterned stamp (step g).

The polymer may include polydimethylsiloxane (PDMS), perfluorinated polyether (PFPE), polyurethane acrylate (PUA), polymethylmethacrylate (PMMA), polyvinyl alcohol (PVA), polyvinyl chloride (PVC), polycarbonate (PC), polytetrafluoroethylene (PTFE), and benzyl methacrylate. Preferably used is polydimethylsiloxane.

Preferably, the multiple-nanopatterned stamp is prepared in a manner in which two kinds of liquid polymers having different viscosities are provided, the liquid polymer having low viscosity is first applied, and the liquid polymer having high viscosity is then applied, followed by thermal treatment.

The multiple-nanopatterned stamp may be used to transfer the pattern like the nanoimprinting stamp.

In addition, the present invention addresses an organic solar cell including the multiple nanopatterns.

The organic solar cell of the present invention may include a first electrode, an electron transport layer formed on the first electrode, a photoactive layer formed on the electron transport layer, a hole transport layer formed on the photoactive layer, and a second electrode formed on the hole transport layer.

The photoactive layer may have multiple nanopatterns formed thereon. The light absorption efficiency of the organic solar cell may be increased by virtue of the multiple nanopatterns.

The electron transport layer is formed of ZnO, LiF, TiOₓ, TiO₂, CsCO₃, Ca and the like, and preferably useful is ZnO. ZnO is used for the hole barrier layer of the organic solar cell, and is advantageous in that a treatment temperature thereof is low and in its ability to realize a uniform surface layer, thus achieving low manufacturing cost and high efficiency compared to when using a-TIPD.

The photoactive layer may include any one selected from the group consisting of PBDTTT-C-T (poly((4,8-bis-(2-ethyl-hexyl-thiophene-5-yl)-benzo(1,2-b:4,5-b′)dithiophene-2,6-diyl)-alt-(2-(2′-ethyl-hexanoyl)-thieno(3,4-b)thiophen-4,6-diyl))), PBDTTT-CF (poly[4,8-bis(2-ethylhexyloxy)-benzo[1,2-b:4,5-b′]dithiophene-2,6-diyl-alt-(4-octanoyl-5-fluoro-thieno[3,4-b]thiophene-2-carboxylate)-2,6-diyl]), P3HT (poly(3-hexylthiophene-2,5-diyl)), PCDTBT (poly[N-9′-heptadecanyl-2,7-carbazole-alt-5,5-(4′,7′-di-2-thienyl-2′,1′,3′-benzothiadiazole)]), MEH-PPV (poly[2-methoxy-5-(2-ethylhexyloxy)-1,4-phenylenevinylene]), PTB7 (poly[[4,8-bis[(2-ethylhexyl)oxy]benzo[1,2-b:4,5-b′]dithiophene-2,6-diyl][3-fluoro-2-[(2-ethylhexyl)carbonyl]thieno[3,4-b]thiophenediyl]]), PTB7-Th (thiophenated-PTB7), PT8 (poly-benzodithiophene-N-alkylthienopyrroledione) and PFN (poly[(9,9-bis(3′-(N,N-dimethylamino)propyl)-2,7-fluorene)-alt-2,7-(9,9-dioctylfluorene)]), and any one selected from the group consisting of PCBM ([6,6]-phenyl-C71-butyric acid methyl ester) and ICBA (1′,1″,4′,4″-Tetrahydro-di[1,4]methanonaphthaleno[1,2:2′,3′,56,60:2″,3″][5,6]fullere ne-C60).

The hole transport layer may include molybdenum oxide (MoO₂, MoO₃). PEDOT:PSS (poly(3,4-ethylenedioxythiophene) polystyrene sulfonate), tungsten oxide (WO₃), nickel oxide, and cerium-doped tungsten oxide (CeWO₃). Preferably used is MoO₃.

The first electrode may include indium tin oxide (ITO), fluorine tin oxide (FTC), a silver nanowire, and a silver nanomesh. Preferably used is ITO.

The second electrode may include Au, Fe, Ag, Cu, Cr, W, Al, Mo, Zn, Ni, Pt, Pd, Co, In, Mn, Si, Ta, Ti, Sn, Pb, V, Ru, Ir, Zr, Rh, and Mg. Preferably used is Au.

In addition, the present invention addresses a method of manufacturing an organic solar cell including the multiple nanopatterns.

Specifically, a first electrode is formed (step a-1).

Preferably, the first electrode is an ITO-coated glass substrate.

Next, an electron transport layer is formed on the first electrode (step b-1).

The electron transport layer is preferably ZnO.

Next, a photoactive layer is formed on the electron transport layer, and multiple nanopatterns are transferred using the multiple-nanopatterned stamp (step c-1).

More specifically, the multiple-nanopatterned stamp is placed on the photoactive layer and vacuum treatment is performed, thereby transferring the multiple nanopatterns. The vacuum treatment may be conducted at 10⁻¹ to 10⁻³ Torr for 5 to 30 min.

Next, a hole transport layer is formed on the photoactive layer (step d-1).

The hole transport layer is preferably formed by thermally depositing molybdenum oxide (MoO₃).

Next, a second electrode is formed on the hole transport layer (step e-1).

The second electrode is preferably formed by thermally depositing gold.

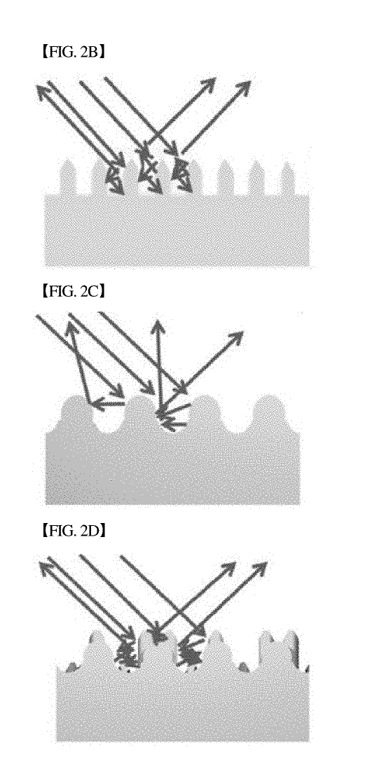

FIGS. 2A to 2D show the principle whereby light absorption efficiency is increased by comparing the multiple nanopatterns of the present invention with a conventional single pattern.

With reference to FIGS. 2A to 2D, the substrate having no pattern (FIG. 2A) and the conventional single-patterned substrates (FIGS. 2B and 2C) absorb a small amount of light compared to the multiple-nanopatterned substrate (FIG. 2D), and the multiple-nanopatterned substrate (FIG. 2D) is capable of increasing light absorption efficiency by virtue of light-scattering effects and plasmonic effects.

Plasmon refers to a pseudo-particle representing collective oscillation of free electrons in the metal. For metal nanoparticles, plasmon is present on a portion of the surface thereof, and thus may be called surface plasmon. Surface plasmon resonance refers to a phenomenon in which an electric field that is remarkably increased is locally generated by coupling plasmon with electromagnetic waves in the range of visible light to near-infrared rays at the interface between a metal and a medium having positive permittivity. This surface plasmon resonance phenomenon may be used to induce light trapping in optoelectronic devices in three ways.

In the first way, the path of light may be increased by causing the scattering effect of light through metal nanoparticles. In the second way, a localized surface plasmon resonance (LSP) effect may be provided, whereby an electric field of light in the specific wavelength range is increased, thus producing a large amount of electrical energy. In the third way, surface plasmon polaritons (SPP) may be provided, whereby a larger amount of light energy may be absorbed through trapping of plasmon polaritons in which electromagnetic waves and plasmon are coupled.

The multiple nanopatterns are responsible for increasing the light absorption efficiency of the optoelectronic device through the above three ways.

### EXAMPLES

A better understanding of the present invention will be given through the following examples, which are merely set forth to illustrate the present invention, but are not to be construed as limiting the scope thereof.

### Preparation Example 1: Formation of Grating Nanopattern (Grating Pattern)

Polystyrene (Mₙ(PS)=192,000 g mol⁻¹, Aldrich) was dissolved in an amount of 2 wt % in toluene to give a polystyrene solution, which was then applied through spin coating to a thickness of about 70 nm on a silicon wafer. Next, thermal treatment was conducted in a vacuum oven at 130° C. for 2 hr, thus forming a polystyrene layer. A polydimethylsiloxane (PDMS) precursor solution (comprising a curing agent and a silicon elastic polymer at a mass ratio of 1:10) was poured on a grating mold (Thorlabs, GH13-36U, Periodicity=278 nm) and cured at 60° C. for 2 hr, thus forming a nanoimprinting stamp. The nanoimprinting stamp was placed on the thermally treated polystyrene layer and pressure was applied at 130° C. for 10 min to thus transfer the grating nanopattern, thus preparing a grating-nanopatterned polystyrene layer.

Using the grating-nanopatterned polystyrene layer as a mask, reactive ion dry etching (RIE) (TTL Dielectric RIE, CF₄/CHF₃/O₂/Ar, flow rate of 10/30/10/10 sccm) was conducted, whereby the grating nanopattern was transferred onto the silicon oxide layer of the silicon wafer, thus manufacturing a grating-nanopatterned silicon wafer.

The surface of the grating-nanopatterned silicon oxide layer was treated with fluorine. Subsequently, a dilute PDMS solution (comprising a curing agent and a silicon elastic polymer at a mass ratio of 1:20) was poured on the silicon layer surface-treated with fluorine, and then a typical PDMS solution (comprising a curing agent and a silicon elastic polymer at a mass ratio of 1:10) was also poured thereon, after which thermal treatment was conducted at 60° C. for 2 hr, thus forming a grating-nanopatterned stamp. The grating-nanopatterned stamp was stripped from the silicon layer before use.

### Preparation Example 2: Formation of Nanopost Pattern (Nanopost Pattern)

Polystyrene-block-polymethylmethacrylate (PS-b-PMMA, Mₙ(PS)=57,000 g mol⁻¹, Mₙ(PMMA)=25,000 g mol⁻¹, M_{w}/Mₙ<1.2, Aldrich) was dissolved in an amount of 2 wt % in toluene to give a block copolymer solution, which was then applied through spin coating to a thickness of about 70 nm on a silicon wafer. Next, thermal treatment was conducted in a vacuum oven at 180° C. for 48 hr, thus forming a phase-separated block copolymer layer. Subsequently, the phase-separated block copolymer layer was irradiated with UV light for 30 min and immersed in acetic acid for 20 min to selectively remove PMMA, thereby forming a nanopost-patterned polystyrene layer.

Thereafter, the preparation of a nanopost-patterned silicon wafer using the nanopost-patterned polystyrene layer as a mask and the preparation of a nanopost-patterned stamp using the nanopost-patterned silicon wafer were carried out in the same manner as in Preparation Example 1.

### Example 1: Formation of Double Nanopattern (Multiple Patterns)

Polystyrene-block-polymethylmethacrylate (PS-b-PMMA, Mₙ(PS)=57,000 g mol⁻¹, Mₙ(PMMA)=25,000 g mol⁻¹, M_{w}/Mₙ<1.2, Aldrich) was dissolved in an amount of 2 wt % in toluene to give a block copolymer solution, which was then applied through spin coating to a thickness of about 70 nm on a silicon wafer. Next, thermal treatment was conducted in a vacuum oven at 180° C. for 48 hr, thus forming a phase-separated block copolymer layer. Subsequently, a polydimethylsiloxane (PDMS) precursor solution (comprising a curing agent and a silicon elastic polymer at a mass ratio of 1:10) was poured on a grating mold (Thorlabs, GH13-36U, Periodicity=278 nm) and cured at 60° C. for 2 hr, thus forming a nanoimprinting stamp. The nanoimprinting stamp was placed on the phase-separated block copolymer layer, and pressure was applied at 130° C. for 10 min to thus transfer the grating pattern, followed by UV irradiation for 30 min and then immersion in acetic acid for 20 min to selectively remove PMMA, thereby preparing a double-nanopatterned polystyrene layer.

Thereafter, the preparation of a double-nanopatterned silicon wafer using the double-nanopatterned polystyrene layer as a mask and the preparation of a double-nanopatterned stamp using the double-nanopatterned silicon wafer were carried out in the same manner as in Preparation Example 1.

### Example 2: Manufacture of Organic Solar Cell (Multiple Patterns)

An ITO (indium tin oxide)-coated glass substrate (EM-Index) was sonicated with acetone and isopropanol for 10 min each. Next, a mixed solution (0.37 M, obtained by adding 2 mL of 1.1 M diethyl zinc solution dissolved in toluene to 4 mL of dry tetrahydrofuran) was applied through spin coating on the glass substrate and thermally treated at 110° C. for 10 min, thus preparing a zinc oxide layer.

Subsequently, 8 mg of PBDTTT-C-T (poly((4,8-bis-(2-ethyl-hexyl-thiophene-5-yl)-benzo(1,2-b:4,5-b′)dithiophene-2,6-diyl)-alt-(2-(2′-ethyl-hexanoyl)-thieno(3,4-b)thiophen-4,6-diyl))), Solarmer) and 12 mg of PC-₇₁BM ([6,6]-phenyl-C71-butyric acid methyl ester, EM Index) were dissolved in 1 mL of dichlorobenzene, and 3 μL of DIO (diiodooctane, EM Index) was then added, followed by thermal treatment at 60° C. for 6 hr, thus preparing an active layer solution. The active layer solution was applied through spin coating on the zinc oxide layer, thus giving an active layer having a thickness of about 80 nm.

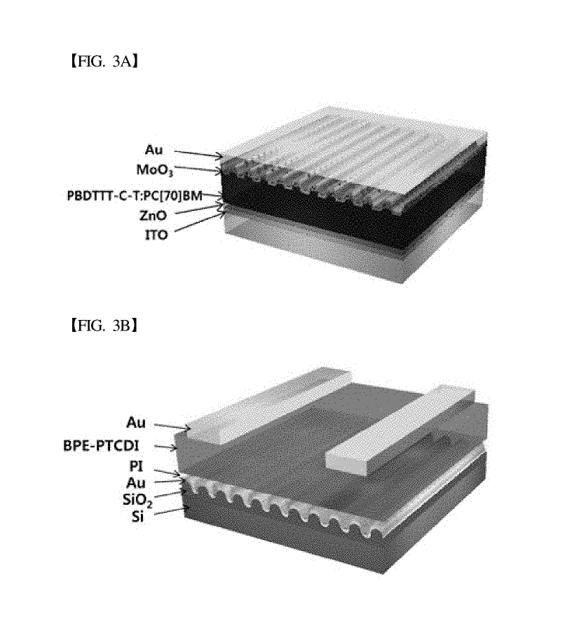

The double-nanopatterned stamp of Example 1 was placed on the active layer, and vacuum treatment (at about 10⁻² Torr) was then performed for 10 min, thus transferring the double nanopattern onto the active layer. The double-nanopatterned stamp was stripped, after which molybdenum oxide (MoO₃) and gold were thermally deposited to respective thicknesses of 5 nm and 100 nm in a vacuum (about 10⁻⁶ Torr) on the active layer, thereby manufacturing an organic solar cell. The organic solar cell is schematically illustrated in FIG. 3A.

### Example 3: Manufacture of Light Transistor (Multiple Patterns)

Chromium and gold were thermally deposited to respective thicknesses of 5 nm and 100 nm on the double-nanopatterned silicon wafer of Example 1. Subsequently, a PI (polyimide) solution was applied through spin coating at 7,000 rpm for 120 sec and thermally treated at 300° C. for 30 min, thus forming a PI film. On the PI film, BPE-PTCDI (N,N-bis(2-phenylethyl)perylene-3,4:9,10-tetracarboxylic diimide) was thermally deposited to a thickness of 40 nm, thus forming a BPE-PTCDI film. A gold electrode was thermally deposited to a thickness of 40 nm on the BPE-PTCDI film using a shadow mask, thereby manufacturing a light transistor. The light transistor is schematically illustrated in FIG. 3B.

### Comparative Example 1:Manufacture of Organic Solar Cell (Flat Pattern)

An organic solar cell was manufactured in the same manner as in Example 2, with the exception that the double nanopattern was not transferred onto the active layer.

### Comparative Example 2: Manufacture of Organic Solar Cell (Grating Pattern)

An organic solar cell was manufactured in the same manner as in Example 2, with the exception that the grating-nanopatterned stamp of Preparation Example 1 was used in lieu of the double-nanopatterned stamp of Example 1.

### Comparative Example 3: Manufacture of Organic Solar Cell (Nanopost Pattern)

An organic solar cell was manufactured in the same manner as in Example 2, with the exception that the nanopost-patterned stamp of Preparation Example 2 was used in lieu of the double-nanopatterned stamp of Example 1.

### Comparative Example 4:Manufacture of Light Transistor (Flat Pattern)

A light transistor was manufactured in the same manner as in Example 3, with the exception that a non-patterned silicon wafer was used in lieu of the double-nanopatterned silicon wafer of Example 1.

### Comparative Example 5: Manufacture of Light Transistor (Grating Pattern)

A light transistor was manufactured in the same manner as in Example 3, with the exception that the grating-nanopatterned silicon wafer of Preparation Example 1 was used in lieu of the double-nanopatterned silicon wafer of Example 1.

### Comparative Example 6: Manufacture of Light Transistor (Nanopost Pattern)

A light transistor was manufactured in the same manner as in Example 3, with the exception that the nanopost-patterned silicon wafer of Preparation Example 2 was used in lieu of the double-nanopatterned silicon wafer of Example 1.

### TEST EXAMPLES

### Test Example 1: Electron Microscopic Image Analysis

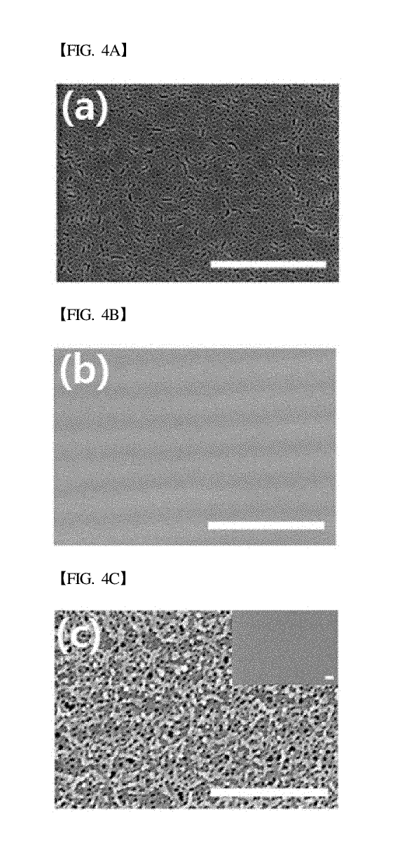

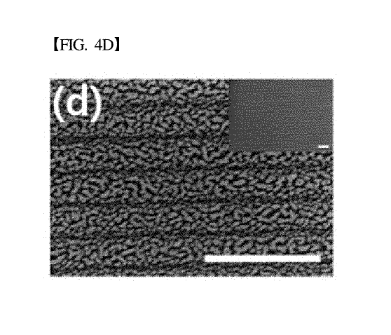

FIG. 4A shows the electron microscope image of the phase-separated block copolymer layer prepared in Example 1, FIG. 4B shows the electron microscope image of the nanoimprinting stamp used in Example 1, FIG. 4C shows the electron microscope image of the double-nanopatterned block copolymer layer prepared in Example 1, and FIG. 4D shows the electron microscope image of the double-nanopatterned silicon wafer prepared in Example 1. In FIGS. 4A to 4D, all of the scale bars are 1 μm.

With reference to FIGS. 4A to 4D, both the nanopattern formed by phase separation of the block copolymer layer (FIG. 4A) and the nanopattern formed by the nanoimprinting stamp (FIG. 4B) were transferred onto the block copolymer layer, whereby the double nanopattern (FIG. 4C) can be seen to be formed. Also, based on the results of inductive coupling plasma (ICP) etching using the double-nanopatterned block copolymer layer as the mask, the double nanopattern can be seen to be efficiently transferred onto the silicon oxide layer of the silicon wafer.

### Test Example 2: Evaluation of Performance of Organic Solar Cell

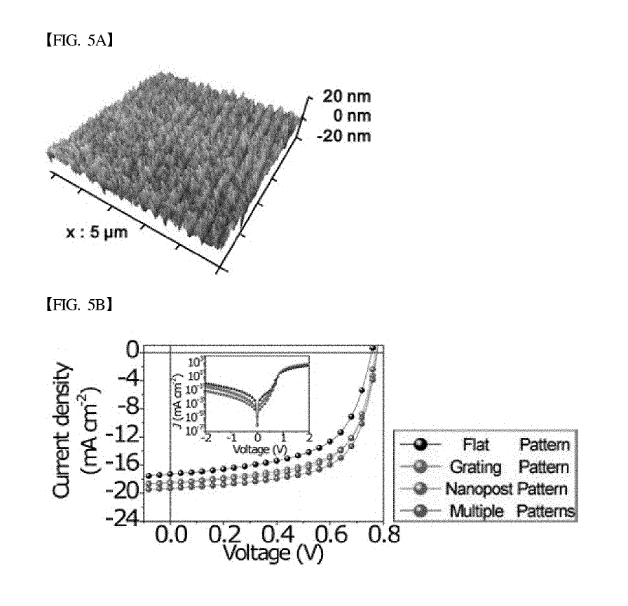

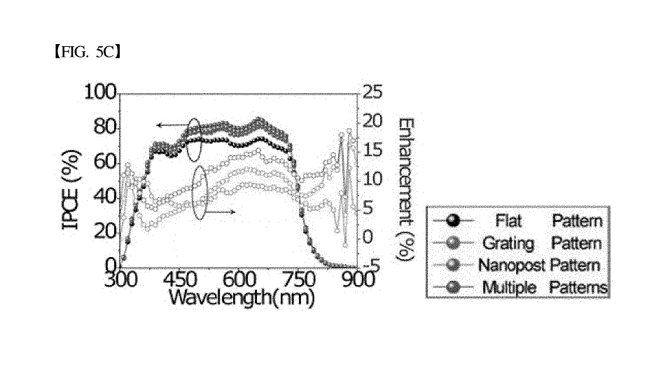

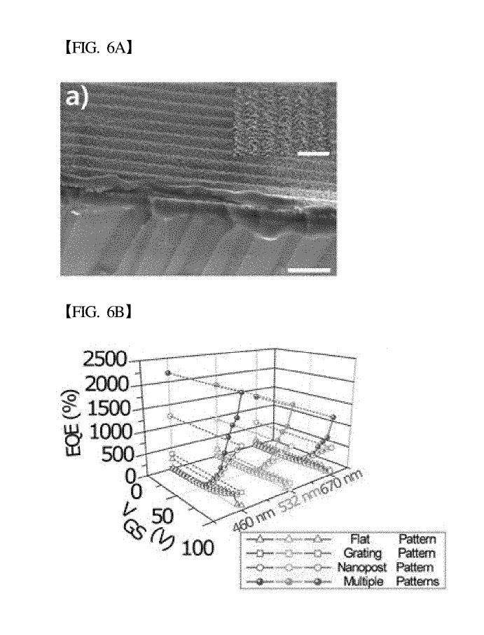

FIG. 5A shows the AFM (Atomic Force Microscopy) image of the active layer of the organic solar cell manufactured in Example 2, FIG. 5B shows the results of measurement of current density depending on the voltage of the organic solar cells manufactured in Example 2 and Comparative Examples 1 to 3, and FIG. 5C shows the results of measurement of internal quantum efficiency of the organic solar cells manufactured in Example 2 and Comparative Examples 1 to 3.

With reference to FIG. 5A, the double nanopattern can be seen to be efficiently formed on the active layer of the organic solar cell manufactured in Example 2.

As shown in FIG. 5B, the organic solar cell manufactured in Example 2 exhibited the lowest current density depending on the voltage. Thus, the organic solar cell including the double nanopattern (Example 2, Multiple Patterns) can be confirmed to produce a large amount of current compared to the organic solar cell in which no pattern was transferred (Comparative Example 1, Flat Pattern) and the organic solar cells in which a single pattern was transferred (Comparative Example 2 (Grating Pattern) and Comparative Example 3 (Nanopost Pattern)).

As shown in FIG. 5C, the organic solar cell manufactured in Example 2 exhibited the highest internal quantum efficiency in the range of 300 to 900 nm. Also, based on the results of comparison of the IPCE enhancement in the organic solar cells manufactured in Example 2 and Comparative Examples 2 and 3 relative to the organic solar cell of Comparative Example 1, in which no pattern was transferred, the IPCE enhancement of the organic solar cell of Example 2 was the highest.

Therefore, when the active layer of the organic solar cell has the double nanopattern, superior light absorption efficiency is exhibited compared to when using the single nanopattern, thereby improving the performance of the organic solar cell.

### Test Example 3: Evaluation of Performance of Light Transistor

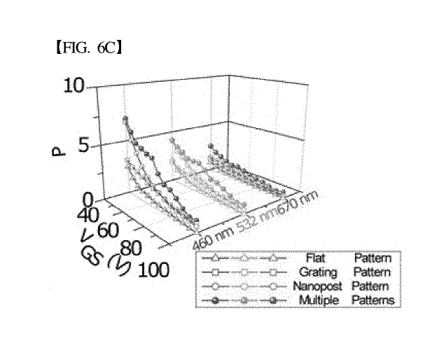

FIG. 6A shows an electron microscope image of the gate electrode of the light transistor manufactured in Example 3, FIG. 6B shows the results of measurement of external quantum efficiency depending on the gate voltage of the light transistors manufactured in Example 3 and Comparative Examples 4 to 6, and FIG. 6C shows the results of measurement of the ratio of photocurrent and dark current depending on the gate voltage of the light transistors manufactured in Example 3 and Comparative Examples 4 to 6.

With reference to FIG. 6A, the double nanopattern can be seen to be efficiently formed on the gate electrode of the light transistor manufactured in Example 3.

As shown in FIG. 6B, the external quantum efficiency (EQE) of the light transistor (Multiple Patterns) manufactured in Example 3 was the highest. In particular, the external quantum efficiency was superior in the range of 460 nm. Thus, the light transistor including the double nanopattern manufactured in Example 3 exhibited high performance in various light ranges, namely 460 nm, 532 nm and 670 nm, compared to the light transistor (Flat Pattern) of Comparative Example 4, in which no pattern was transferred, and compared to the light transistors (Grating Pattern and Nanopost Pattern) of Comparative Examples 5 and 6, in which a single pattern was transferred. Moreover, as the gate voltage was increased, the external quantum efficiency (EQE) was drastically increased, and an increase in the EQE of the light transistor including the double nanopattern manufactured in Example 3 was maximized.

As shown in FIG. 6C, the ratio of photocurrent and dark current depending on the gate voltage of the light transistor manufactured in Example 3 was the highest. The properties thereof were maintained in various light ranges, namely 460 nm, 532 nm and 670 nm, and in particular, the highest ratio was manifested at 460 nm. Therefore, the light transistor of the present invention, the gate electrode of which has the double nanopattern, can be confirmed to induce an increase in light absorption efficiency to thereby increase light reactivity.

The scope of the invention is represented by the claims below rather than the aforementioned detailed description, and all of the changes or modified forms that are capable of being derived from the meaning, range, and equivalent concepts of the appended claims should be construed as being included in the scope of the present invention.

What is claimed is:

1. A method of forming multiple nanopatterns, comprising:
(a) forming a block copolymer layer on a substrate;
(b) self-assembling the block copolymer layer, thus preparing a phase-separated block copolymer layer including a plurality of patterns;
(c) performing stamping on the phase-separated block copolymer layer using a nanoimprinting stamp having a nano-sized pattern;
(d) removing at least one from the plurality of patterns, thus preparing a multiple-nanopatterned block copolymer layer;
(e) performing etching using the multiple-nanopatterned block copolymer layer as a mask, thus preparing a multiple-nanopatterned substrate;
(f) subjecting the multiple-nanopatterned substrate to surface treatment; and
(g) applying a liquid polymer on the multiple-nanopatterned substrate and then performing thermal treatment, thus preparing a multiple-nanopatterned stamp.

2. The method of claim 1, wherein the plurality of patterns includes a first pattern and a second pattern.

3. The method of claim 2, wherein the block copolymer layer includes at least one selected from among polystyrene-block-polymethylmethacrylate, polystyrene-block-polyvinylpyridine (polystyrene-block-poly-4-vinylpyridine, polystyrene-block-poly-2-vinylpyridine), polystyrene-block-polydimethylsiloxane, 4-(tert-butyldimethylsilyl)oxystyrene, polystyrene-block-poly(butadiene), polystyrene-block-polyimide, polystyrene-block-poly(ethylene oxide), polystyrene-block-polyferrocenylsilane, and polystyrene-block-polyferrocenylsilane-block-poly-2-vinylpyridine.

4. The method of claim 1, wherein the nanoimprinting stamp includes at least one selected from among polydimethylsiloxane (PDMS), perfluorinated polyether (PFPE), polyurethane acrylate (PUA), polymethylmethacrylate (PMMA), polyvinyl alcohol (PVA), polyvinyl chloride (PVC), polycarbonate (PC), polytetrafluoroethylene (PTFE), and benzyl methacrylate.

5. The method of claim 1, wherein step (a) comprises:
(a′) forming a block copolymer layer by applying a block copolymer solution on the substrate.

6. The method of claim 5, wherein a solvent for the block copolymer solution includes at least one selected from among toluene, dichloroethylene, trichloroethylene, chloroform, chlorobenzene, dichlorobenzene, styrene, dimethylformamide, dimethylsulfoxide, xylene, cyclohexene, isopropyl alcohol, ethanol, methanol, tetrahydrofuran, terpineol, ethylene glycol, diethylene glycol, polyethylene glycol, acetonitrile, and acetone.

7. The method of claim 1, wherein step (d) comprises:
(d′) removing at least one from the plurality of patterns by performing both wet etching and UV irradiation.

8. The method of claim 1, wherein the etching in step (e) is performed using inductive coupling plasma (ICP) etching or reactive ion etching (RIE).

9. The method of claim 8, wherein the inductive coupling plasma (ICP) etching or reactive ion etching (RIE) is performed by inducing CF₄/CHF₃/O₂/Ar gas to flow at a flow rate of 0.1 to 10/10 to 50/0.1 to 10/0.1 to 10 sccm.

10. The method of claim 1, wherein the surface treatment in step (f) is performed by treating a surface of the multiple-nanopatterned substrate with fluorine.

11. The method of claim 1, wherein the polymer in step (g) includes at least one selected from among polydimethylsiloxane (PDMS), perfluorinated polyether (PFPE), polyurethane acrylate (PUA), polymethylmethacrylate (PMMA), polyvinyl alcohol (PVA), polyvinyl chloride (PVC), polycarbonate (PC), polytetrafluoroethylene (PTFE), and benzyl methacrylate.

12. An organic solar cell, comprising:
a first electrode;
an electron transport layer formed on the first electrode;
a photoactive layer formed on the electron transport layer;
a hole transport layer formed on the photoactive layer; and
a second electrode formed on the hole transport layer,
wherein the photoactive layer includes multiple nanopatterns.

13. The organic solar cell of claim 12, wherein the electron transport layer includes at least one selected from among ZnO, LiF, TiOₓ, TiO₂, CsCO₃, and Ca.

14. The organic solar cell of claim 12, wherein the photoactive layer includes any one selected from the group consisting of PBDTTT-C-T, PBDTTT-CF, P3HT, PCDTBT, PCTDTBT, MEH-PPV, PTB7, PTB7-Th, PT8 and PFN and any one selected from the group consisting of PCBM and ICBA.

15. The organic solar cell of claim 12, wherein the hole transport layer includes at least one selected from among molybdenum oxide (MoO₂, MoO₃), PEDOT:PSS (poly(3,4-ethylenedioxythiophene) polystyrene sulfonate), tungsten oxide (WO₃), nickel oxide, and cerium-doped tungsten oxide (CeWO₃).

16. The organic solar cell of claim 12, wherein the first electrode includes at least one selected from among indium tin oxide (ITO), fluorine tin oxide (FTO), a silver nanowire, and a silver nanomesh.

17. The organic solar cell of claim 12, wherein the second electrode includes at least one selected from among Au, Fe, Ag, Cu, Cr, W, Al, Mo, Zn, Ni, Pt, Pd, Co, In, Mn, Si, Ta, Ti, Sn, Pb, V, Ru, Ir, Zr, Rh, and Mg.

18. A method of manufacturing an organic solar cell, comprising:
(a-1) forming a first electrode;
(b-1) forming an electron transport layer on the first electrode;
(c-1) forming a photoactive layer on the electron transport layer and transferring multiple nanopatterns using the multiple-nanopatterned stamp of claim 1;
(d-1) forming a hole transport layer on the photoactive layer; and
(e-1) forming a second electrode on the hole transport layer.
